(19) United States
(12) Patent Application Publication
(10) Pub. No.: US 2010/0140596 A1
(43) Pub. Date: Jun. 10, 2010

(54) ORGANIC THIN FILM TRANSISTOR AND METHOD OF MANUFACTURING THE SAME

(75) Inventors: Yong-Young Noh, Yuseong-gu (KR); Seok-Ju Kang, Buk-gu (KR); Jae Bon Koo, Yuseong-gu (KR); In-Kyu You, Yuseong-gu (KR); Kang-Jun Baeg, Buk-gu (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/498,910

(22) Filed: Jul. 7, 2009

(30) Foreign Application Priority Data
Dec. 8, 2008 (KR) 10-2008-0124026
Mar. 31, 2009 (KR) 10-2009-0027376

(51) Int. Cl. H01L 51/30; H01L 51/40

(52) U.S. Cl. 257/40; 438/99; 257/E51.025; 257/E51.027

(57) ABSTRACT

Provided is an organic thin film transistor and method of forming the same. The organic thin film transistor can decrease threshold voltage and driving voltage by forming a thin organic dielectric layer in a lamella structure using a diblock copolymer including a hydrophilic polymer with high permittivity and a hydrophobic polymer with low permittivity together. Also, the method can simplify the manufacturing process by forming an organic dielectric layer including polymers having two different physical properties through one spin coating.

### CROSS-REFERENCE TO RELATED APPLICATIONS

This U.S. non-provisional patent application claims priorities under 35 U.S.C. § 119 of Korean Patent Application Nos. 10-2008-0124026, filed on Dec. 8, 2008 and 10-2009-0027376, filed on Mar. 31, 2009, the entire contents of which are hereby incorporated by reference.

### BACKGROUND OF THE INVENTION

The present invention disclosed herein relates to an organic thin film transistor and a method of manufacturing the same.

Organic thin film transistors (OTFTs) have been actively researched because they can be manufactured through a low temperature solution process and thus be applied to a variety of flexible electronic devices on polymer substrates, such as a driving element of a driver unit for electronic paper or flexible display, a circuit for a radio frequency identification (RFID) tag, or the like. Polymer semiconductor and dielectric materials, which can be used in solution-state processes, are highly advantageous commercially because they can be applied in roll-to-roll processing, which can remarkably reduce OTFT manufacturing costs. Of the above two materials, solution-state processible polymer dielectric material has been the subject of much research recently because of the advantage presented by its solution processibility in spite of its low permittivity relative to other materials. When polymer material with low permittivity is used as a gate dielectric, however, it requires a high driving voltage or threshold voltage relative to other materials of the same thickness. Thus, when transistors are driven, considerable power is consumed and much heat is generated—the latter of which can shorten the service life of the transistors. For this reason, much research activity has focused on using polymer dielectrics with high permittivity as gate dielectrics, and making inorganic dielectrics with high permittivity in the form of nanoparticles and mixing the inorganic dielectrics made of nanoparticles with polymer dielectrics to obtain high permittivity. However, when such a high permittivity polymer is used as a gate dielectric, many dipoles (which are generated in the dielectric and are randomly aligned at an interface between the semiconductor and the dielectric) adversely affect movement of carriers in an adjacent semiconductor polymer thin film, deteriorating transistor performance. These problems make it difficult to manufacture an OTFT that uses a polymer dielectric and can also achieve low driving voltage and high charge mobility.

### SUMMARY OF THE INVENTION

The present invention provides an OTFT that can lower the driving voltage and threshold voltage.

The present invention also provides a method of manufacturing an OTFT that can simply the manufacturing process.

Embodiments of the present invention provide organic thin film transistors including: a substrate; an organic dielectric layer on the substrate; a gate electrode adjacent to one surface of the organic dielectric layer; an active layer adjacent to an opposite surface of the organic dielectric layer; and source/drain electrodes adjacent to both sides of the gate electrode and contacting the active layer, wherein the organic dielectric layer includes a diblock copolymer forming a lamella structure.

In some embodiments, the diblock copolymer includes a hydrophilic polymer having a high permittivity and a hydrophobic polymer having a low permittivity. The hydrophilic polymer may be at least one selected from the group consisting of poly(2-vinyl pyridine) or poly(4-vinyl pyridine), poly(4-vinyl phenol), polyvinyl pyridine, polyacrylonitrile, polychloroprene, poly(vinylidene fluoride) and poly(vinylidene chloride). The hydrophobic polymer may be at least one selected from the group consisting of polybutadiene, polystyrene, polyisobutylene, poly(methyl methacrylate), polycarbonate, polychlorotrifluoroethylene, polyethylene, polypropylene, polytetrafluoroethylene, CYTOP™, and polypropylene-co-butene. The hydrophilic polymer has a volume fraction of 0.35 to 0.65 with respect to a total volume of the diblock copolymer.

In other embodiments, the active layer may be at least one selected from the group consisting of single crystal silicon, single crystal germanium, poly(9,9-dioctylfuorene-co-bithiophene), poly(3-hexylthiophene), polythiophene, thieno thiophene, triisopropylsilyl pentacene, pentacene precursor, α-6-thiophene, polyfluorene, pentacene, tetracene, anthracene, perylene, rubrene, coronene, perylene tetracarboxylic diimide, polyparaphenylene vinylene, polythiophene vinylene, oligothiophene of α-5-thiophene, metal phthalocyanine or metal free phthalocyanine, and naphthalene tetra carboxylic acid diimide, and their derivatives.

In still other embodiments, the gate electrode and the source/drain electrodes may be at least one selected from the group consisting of gold (Au), silver (Ag), aluminum (Al), nickel (Ni), indium tin oxide (ITO), polyethylenedioxythiophene:polystyrene sulfonate (PEDOT:PSS), polypyrrole, and polyaniline.

In other embodiments of the present invention, methods of manufacturing an organic thin film transistor include: coating a solution including a diblock copolymer on a substrate; thermally treating the substrate to form an organic dielectric layer including the diblock copolymer having a lamella structure on the substrate; forming a gate electrode adjacent to one surface of the organic dielectric layer; forming an active layer adjacent to an opposite surface of the organic dielectric layer; and forming source/drain electrodes adjacent to both sides of the gate electrode and contacting the active layer.

In some embodiments, the solution including the diblock copolymer may be made by dissolving a hydrophilic polymer with high permittivity and a hydrophobic polymer with low permittivity in a solvent.

In other embodiments, the solvent is an organic solvent. In one example, the organic solvent is propylene glycol methyl ether acetate (PGMEA).

In still further embodiments, the hydrophilic polymer and the hydrophobic polymer may be dissolved in the solvent in the amount of about 2 wt % to about 10 wt %.

In even other embodiments, the thermally treating of the substrate may be performed at a temperature equal to or more than glass transition temperature (Tg) of the diblock copolymer and of less than decomposition temperature (Td). Alternatively, the thermally treating of the substrate may be performed at a temperature less than or equal to glass transition temperature (Tg) of the diblock copolymer in an atmosphere including vapor of the solvent.

In yet other embodiments, the thermally treating of the substrate comprises vaporizing the solvent and making the diblock copolymer form the lamella structure.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view of an organic thin film transistor (OTFT) according to an embodiment of the present invention;

FIG. 2A is a schematic view of a diblock copolymer according to an embodiment of the present invention;

FIG. 2B is a schematic view illustrating that diblock copolymers form a lamella structure according to an embodiment of the present invention;

FIG. 3 is a cross-sectional view of an organic thin film transistor according to another embodiment of the present invention;

FIG. 4 is a cross-sectional view of an organic thin film transistor according to a further embodiment of the present invention.

FIG. 5A is a photograph of a top surface of an organic dielectric layer including poly(2-vinyl pyridine)-polystyrene diblock copolymer manufactured according to an embodiment of the present invention, and is taken by an optical microscope;

FIG. 5B is a photograph of a top surface of an organic dielectric layer including poly(2-vinyl pyridine)-polystyrene diblock copolymer manufactured according to an embodiment of the present invention, and is taken by an atomic force microscope (AFM), [Unit: um];

FIG. 6 is a photograph showing a cross-sectional view of an organic dielectric layer including poly(2-vinyl pyridine)-polystyrene diblock copolymer manufactured according to an embodiment of the present invention; and is taken by an scanning electron microscope (SEM);

FIG. 7 is a graph showing output curves obtained from a pentacene organic thin film transistor manufactured using a poly(2-vinyl pyridine)-polystyrene diblock copolymer as a dielectric according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

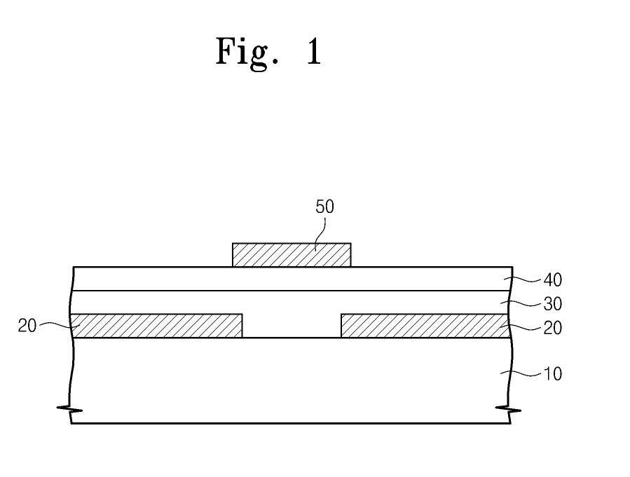

FIG. 1 is a cross-sectional view of an organic thin film transistor (OTFT) according to an embodiment of the present invention.

Referring to FIG. 1, two source/drain electrodes 20 are disposed spaced apart from each other on a substrate 10. An active layer 30 covers the substrate 10 exposed between the source and drain electrodes 20, and the source/drain electrodes 20. The active layer 30 is covered with an organic dielectric layer 40. A gate electrode 50 is disposed between the source and drain electrodes 20 on the organic dielectric layer 40 to constitute a single OTFT.

The active layer 30 may be formed of single crystal silicon, single crystal germanium, poly(9,9-dioctylfuorene-co-bithiophene), poly(3-hexylthiophene), polythiophene, thieno thiophene, triisopropylsilyl pentacene, pentacene precursor, α-6-thiophene, polyfluorene, pentacene, tetracene, anthracene, perylene, rubrene, coronene, perylene tetracarboxylic diimide, polyparaphenylene vinylene, polythiophene vinylene, oligothiophene of α-5-thiophene, metal phthalocyanine or metal free phthalocyanine, and naphthalene tetra carboxylic acid diimide, and their derivatives.

The gate electrode 50 and the source/drain electrodes 20 may be at least one selected from the group consisting of gold (Au), silver (Ag), aluminum (Al), nickel (Ni), indium tin oxide (ITO), polyethylenedioxythiophene:polystyrene sulfonate (PEDOT:PSS), polypyrrole, and polyaniline. The substrate 10 may be an n-doped or p-doped silicon wafer, or an organic substrate coated with one selected from the group consisting of polyethersulphone, polyacrylate, polyetherimide, polyimide and polyethyleneterepthalate, and indium tin oxide (ITO).

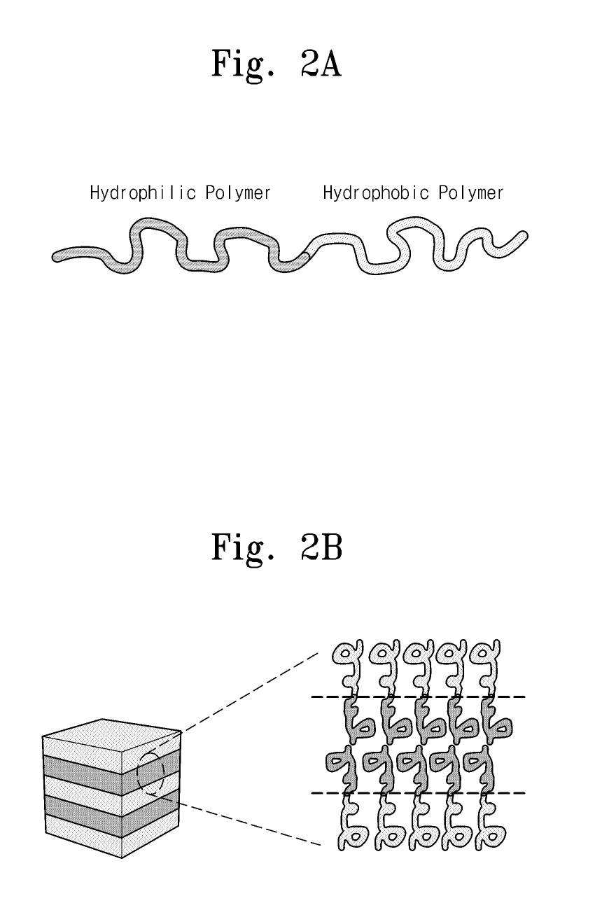

The organic dielectric layer 40 includes a diblock copolymer, which will be described with reference to FIGS. 2A and 2B. FIG. 2A is a schematic view of a diblock copolymer according to an embodiment of the present invention. FIG. 2B is a schematic view illustrating that a diblock copolymer forms a lamella structure according to an embodiment of the present invention.

The diblock copolymer may have a configuration in which a hydrophilic polymer with high permittivity and a hydrophobic polymer with low permittivity are copolymerized with each other, as shown in FIG. 2A. The permittivity (ε) of the hydrophilic polymer is preferably 4 or more, for example, 4 to 12.2. The permittivity (ε) of the hydrophobic polymer is preferably 3.2 or less, for example, 2.1 to 3.2. The hydrophilic polymer (permittivity is expressed in parenthesis) may be selected from the group consisting of poly(4-vinyl phenol) (ε=4.5), polyvinyl pyridine (ε=4), polyacrylonitrile (ε=5.5), polychloroprene (ε=6.6), poly(vinylidene fluoride) (ε=12.3), and poly(vinylidene chloride) (ε=4.6). The hydrophobic polymer may be at least one selected from the group consisting of polybutadiene (ε=2.5), polystyrene (ε=2.6), polyisobutylene (ε=2.2), poly(methyl methacrylate) (ε=3.2), polycarbonate (ε=2.9), polychlorotrifluoroethylene (ε=2.65), polyethylene (ε=2.3), polypropylene (ε=2.3), polytetrafluoroethylene (ε=2.1), CYTOP™ (ε=2.1), and polypropylene-co-butene (ε=2.3). The hydrophilic polymer has a volume fraction of 0.35 to 0.65 with respect to a total volume of the diblock copolymer. The diblock copolymer forms a lamella structure in the organic dielectric layer 40 as shown in FIG. 2B.

A method of manufacturing the OTFT shown in FIG. 1 will be described with reference to FIG. 1. First, source and drain electrodes 20 spaced apart from each other are formed on the substrate 10. Source and drain electrodes 20 may be formed through deposition, photolithography and etching processes. Alternatively, source and drain electrodes 20 may be formed through an inkjet printing of conductive ink. After source and drain electrodes 20 are formed, active layer 30 is formed. Active layer 30 may be formed through spin coating or inkjet printing of polymer material, or high vacuum evaporation of organic monomer material. A solution including a diblock copolymer is spin-coated on the resultant substrate 10 including the active layer 30. The solution including a diblock copolymer may be prepared by dissolving a hydrophilic polymer with high permittivity and a hydrophobic polymer with low permittivity in a solvent. The hydrophilic polymer and the hydrophobic polymer may be preferably dissolved in the solvent in the amount of 2 wt % to 10 wt %. The solvent may be preferably an organic solvent, for example, propylene glycol methyl ether acetate (PGMEA). By dissolving the hydrophilic polymer with high permittivity and the hydrophobic polymer with low permittivity in the solvent, the solution including a diblock copolymer is prepared, and at this time, the hydrophilic polymer exists at a volume fraction of 0.35 to 0.65 in the diblock copolymer. That is, the hydrophilic polymer may be added such that the hydrophilic polymer has a volume fraction of 0.35 to 0.65 with respect to a total volume of the polymers added in the solvent. The solution is spin-coated on the active layer 30. The spin coating may be performed at a speed of 2000-4000 rpm. In this case, since there are shown characteristics that two blocks in the diblock copolymer in the solution push each other by a repulsive force and minimize an interfacial area therebetween, hydrophilic polymers face each other or hydrophobic polymers face each other to form the lamella structure as shown in FIG. 2B. These characteristics may be different depending on surface property of the layer on which the solution is coated, i.e., which the solution contacts. In other words, when the surface of the layer on which the solution is coated is hydrophobic, hydrophobic groups in the lamella structure may be positioned at an outside and hydrophilic groups may be positioned at an inside. When the surface of the layer on which the solution is coated is hydrophilic, hydrophobic groups in the lamella structure may be positioned at an inside and hydrophilic groups may be positioned at an outside, which is opposed to the above case. However, it is difficult to form a perfect lamella structure only by the preparation of solution and the spin coating. To form a perfect lamella structure and remove solvent unnecessary in the solution, a heat treatment process is performed. The heat treatment process may be performed at a temperature equal to or more than glass transition temperature (Tg) of the diblock copolymer and of less than decomposition temperature (Td). The heat treatment process may be performed in a hot plate or vacuum oven for 12-36 hours. Alternatively, the heat treatment process of the substrate may be performed at a temperature less than or equal to glass transition temperature (Tg) of the diblock copolymer in an atmosphere including vapor of the solvent. For example, the heat treatment process may be performed at a temperature of about 90-110° C. By doing so, it is possible to form the organic dielectric layer 40. The gate electrode 50 on the organic dielectric layer 40 may be formed by the same method as that used for forming the source/drain electrodes 20. Through the above processes, the OTFT can be manufactured.

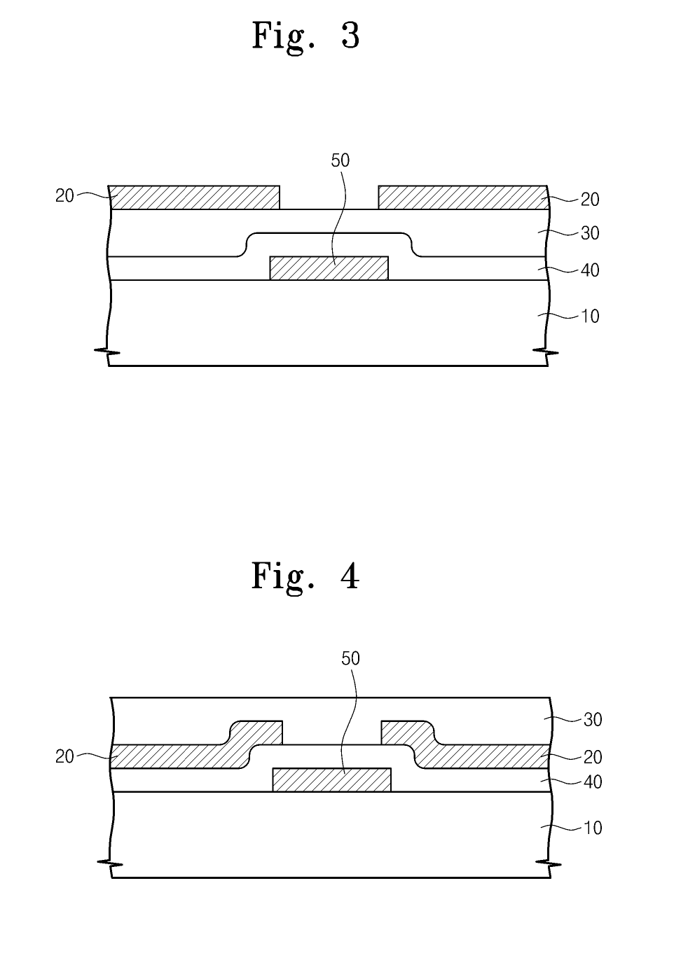

The organic dielectric layers according to embodiments of the present invention may be also applied to OTFT structures shown in FIGS. 3 and 4, respectively.

Referring to FIG. 3, a gate electrode 50 is disposed on a substrate 10, and an organic dielectric layer 40 and an active layer 30 are sequentially stacked on the substrate 10 including the gate electrode 50. Source and drain electrodes 20 spaced apart from each other are disposed at both sides of the gate electrode 50 on the active layer 30, thus constituting a single OTFT.

Alternatively, referring to FIG. 4, a gate electrode 50 is disposed on a substrate 10, and a gate dielectric layer 40 is disposed on the substrate 10 including the gate electrode 50. Source and drain electrodes 20 spaced apart from each other are disposed at both sides of the gate electrode 50 on the gate dielectric layer 40. An active layer 30 covers the gate dielectric layer 40 exposed between the source and drain electrodes 20.

In OTFTs having various structures as shown in FIGS. 3 and 4, it can be understood that arrangement of the electrodes 50, 20 and layers 40, 30 may be changed but types and forming methods of the electrodes 50, 20 and layers 40, 30 may be the same as those described with reference to FIG. 1.

### Embodiment 1

### Manufacturing of Organic Dielectric Layer

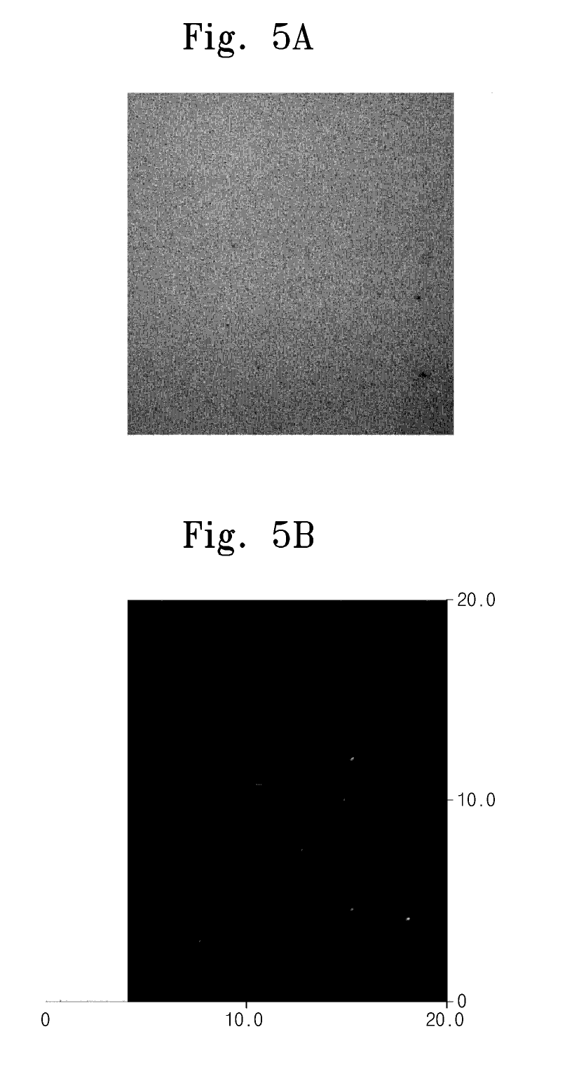

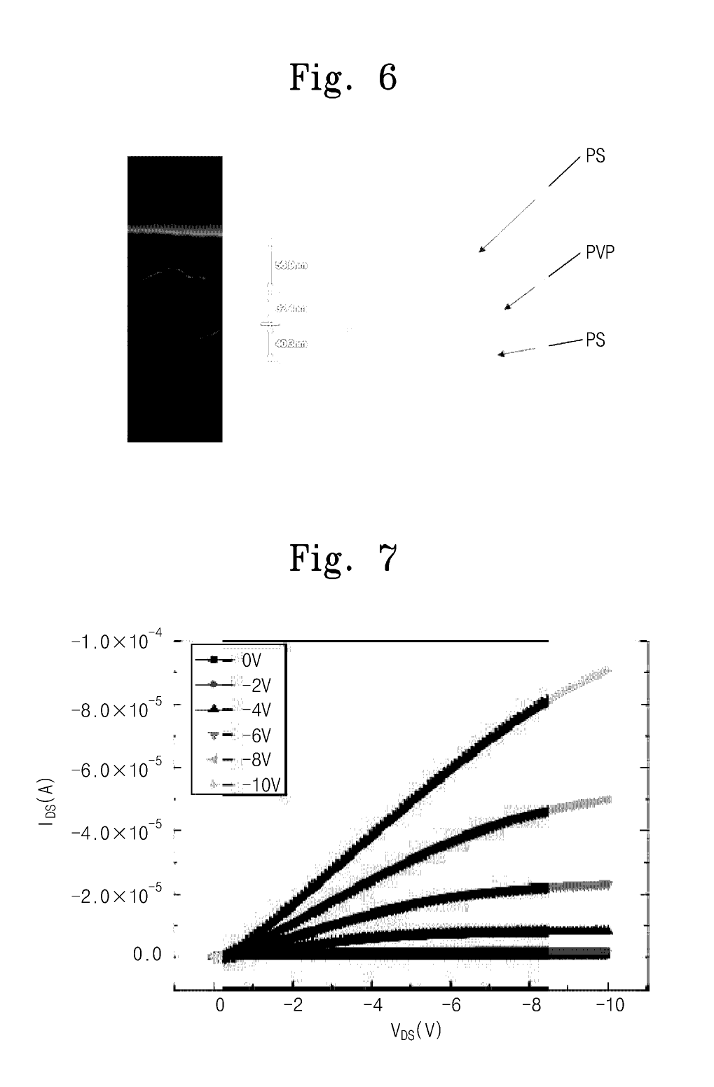

A hydrophilic block polymer with high permittivity, for example, poly(2-vinyl pyridine), and a hydrophobic block polymer with low permittivity, for example, polystyrene are added at a volume ratio of 0.5:0.5 in PGMEA and dissolved to prepare a solution including a diblock copolymer. Each block polymer has a number-average molecular weight of about 78,000 g/gmol, and the solution has a concentration of about 4% by weight. The solution is spin-coated at a speed of 2500 rpm on a substrate. Thereafter, the substrate spin-coated with the solution is heat-treated in a vacuum oven maintained in a high vacuum state at about 180° C. for 12 hours to form an organic dielectric layer. FIG. 5A is a photograph of a top surface of an organic dielectric layer including poly(2-vinyl pyridine)-polystyrene diblock copolymer manufactured according to this exemplary embodiment of the present invention, and is taken by an optical microscope. FIG. 5B is a photograph of a top surface of an organic dielectric layer including poly(2-vinyl pyridine)-polystyrene diblock copolymer manufactured according to this exemplary embodiment of the present invention, and is taken by an atomic force microscope (AFM). In FIG. 5B, the unit of values around the photograph is μm. When reviewing FIGS. 5A and 5B, it can be understood that only one type of polymer is uniformly distributed on the top surface of the organic dielectric layer. That is, it can be understood that only the polystyrene, which is one of the two blocks constituting the diblock copolymer, is exposed on the top surface of the organic dielectric layer. FIG. 6 is a photograph showing a sectional surface of an organic dielectric layer including poly(2-vinyl pyridine)-polystyrene diblock copolymer manufactured according to this exemplary embodiment of the present invention, and is taken by a scanning electron microscope (SEM). Referring to FIG. 6, it can be understood that PVP {poly(2-vinyl pyridine)} is positioned at a central portion of the organic dielectric layer and PS (polystyrene) is positioned at a bottom surface and the top surface of the organic dielectric layer to well form a lamella structure.

### Embodiment 2

An OTFT having the structure shown in FIG. 1 is manufactured. A substrate is formed of glass, source and drain electrodes are made of gold (Au), an active layer is formed of pentacene, and a gate electrode is formed of aluminum (Al). An organic dielectric layer is formed in the same method as that of Embodiment 1. In the OTFT manufactured as above, 0V to −10V is applied to the gate electrode and a voltage (V_{DS}) of 0V to −10V is applied to the source/drain electrodes. At this time, output current (I_{DS}) is measured and shown on the graph of FIG. 7. From FIG. 7, it can be understood that the OTFT normally operates with the charge carrier mobility of 0.5 cm²/Vs and at very low operating voltage.

As described above, the organic thin film transistors of the present invention can decrease threshold voltage and driving voltage by forming a thin organic dielectric layer in a lamella structure using a diblock copolymer including a hydrophilic polymer with high permittivity and a hydrophobic polymer with low permittivity together. Also, the methods of manufacturing an organic thin film transistor according to the present invention can simplify the manufacturing process by forming an organic dielectric layer including polymers having two different physical properties through one spin coating.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An organic thin film transistor comprising:
a substrate;
an organic dielectric layer on the substrate;
a gate electrode adjacent to one surface of the organic dielectric layer;
an active layer adjacent to an opposite surface of the organic dielectric layer; and
source/drain electrodes adjacent to both sides of the gate electrode and contacting the active layer,
wherein the organic dielectric layer includes a diblock copolymer forming a lamella structure.

2. The organic thin film transistor of claim 1, wherein the diblock copolymer comprises a hydrophilic polymer having high permittivity and a hydrophobic polymer having low permittivity.

3. The organic thin film transistor of claim 2, wherein the hydrophilic polymer is at least one selected from the group consisting of poly(2-vinyl pyridine) or poly(4-vinyl pyridine), poly(4-vinyl phenol), polyvinyl pyridine, polyacrylonitrile, polychloroprene, poly(vinylidene fluoride) and poly(vinylidene chloride).

4. The organic thin film transistor of claim 2, wherein the hydrophobic polymer is at least one selected from the group consisting of polybutadiene, polystyrene, polyisobutylene, poly(methyl methacrylate), polycarbonate, polychlorotrifluoroethylene, polyethylene, polypropylene, polytetrafluoroethylene, CYTOP™, and polypropylene-co-butene.

5. The organic thin film transistor of claim 2, wherein the hydrophilic polymer has a volume fraction of 0.35 to 0.65 with respect to a total volume of the diblock copolymer.

6. The organic thin film transistor of claim 1, wherein the active layer is at least one selected from the group consisting of poly(9,9-dioctylfuorene-co-bithiophene), poly(3-hexylthiophene), polythiophene, thieno thiophene, triisopropylsilyl pentacene, pentacene precursor, α-6-thiophene, polyfluorene, pentacene, tetracene, anthracene, perylene, rubrene, coronene, perylene tetracarboxylic diimide, polyparaphenylene vinylene, polythiophene vinylene, oligothiophene of α-5-thiophene, phthalocyanine with or without metal, and naphthalene tetra carboxylic acid diimide, and their derivatives.

7. The organic thin film transistor of claim 1, wherein the gate electrode and the source/drain electrodes are at least one selected from the group consisting of gold (Au), silver (Ag), aluminum (Al), nickel (Ni), indium tin oxide (ITO), polyethylenedioxythiophene:polystyrene sulfonate (PEDOT:PSS), polypyrrole, and polyaniline.

8. A method of manufacturing an organic thin film transistor, the method comprising:
coating a solution including a diblock copolymer on a substrate;
thermally treating the substrate to form an organic dielectric layer including the diblock copolymer having a lamella structure on the substrate;
forming a gate electrode adjacent to one surface of the organic dielectric layer;
forming an active layer adjacent to an opposite surface of the organic dielectric layer; and
forming source/drain electrodes adjacent to both sides of the gate electrode and contacting the active layer.

9. The method of claim 8, wherein the solution including the diblock copolymer is prepared by dissolving a hydrophilic polymer with high permittivity and a hydrophobic polymer with low permittivity in a solvent.

10. The method of claim 9, wherein the hydrophilic polymer is at least one selected from the group consisting of poly(2-vinyl pyridine) or poly(4-vinyl pyridine), poly(4-vinyl phenol), polyvinyl pyridine, polyacrylonitrile, polychloroprene, poly(vinylidene fluoride) and poly(vinylidene chloride).

11. The method of claim 9, wherein the hydrophobic polymer is at least one selected from the group consisting of polybutadiene, polystyrene, polyisobutylene, poly(methyl methacrylate), polycarbonate, polychlorotrifluoroethylene, polyethylene, polypropylene, polytetrafluoroethylene, CYTOP™, and polypropylene-co-butene.

12. The method of claim 9, wherein the solvent is an organic solvent.

13. The method of claim 12, wherein the organic solvent is propylene glycol methyl ether acetate (PGMEA).

14. The method of claim 9, wherein the hydrophilic polymer and the hydrophobic polymer are dissolved in the solvent in the amount of about 2 wt % to about 10 wt %.

15. The method of claim 8, wherein the thermally treating of the substrate is performed at a temperature equal to or more than glass transition temperature (Tg) of the diblock copolymer and of less than decomposition temperature (Td).

16. The method of claim 9, wherein the thermally treating of the substrate is performed at a temperature less than or equal to glass transition temperature (Tg) of the diblock copolymer in an atmosphere including vapor of the solvent.

17. The method of claim 9, wherein the thermally treating of the substrate comprises vaporizing the solvent and making the diblock copolymer form the lamella structure.

18. The method of claim 9, wherein the hydrophilic polymer has a volume fraction of 0.35 to 0.65 with respect to a total volume of the diblock copolymer.

19. The method of claim 8, wherein the active layer is at least one selected from the group consisting of poly(9,9-dioctylfuorene-co-bithiophene), poly(3-hexylthiophene), polythiophene, thieno thiophene, triisopropylsilyl pentacene, pentacene precursor, α-6-thiophene, polyfluorene, pentacene, tetracene, anthracene, perylene, rubrene, coronene, perylene tetracarboxylic diimide, polyparaphenylene vinylene, polythiophene vinylene, oligothiophene of α-5-thiophene, phthalocyanine with or without metal, and naphthalene tetra carboxylic acid diimide, and their derivatives.

20. The method of claim 8, wherein the gate electrode and the source/drain electrodes are at least one selected from the group consisting of gold (Au), silver (Ag), aluminum (Al), nickel (Ni), indium tin oxide (ITO), polyethylenedioxythiophene:polystyrene sulfonate (PEDOT:PSS), polypyrrole, and polyaniline.
